(19) United States
(12) Patent Application Publication
(10) Pub. No.: US 2015/0059835 A1
(43) Pub. Date: Mar. 5, 2015

(54) Photoelectric Conversion Device

(71) Applicant: PANASONIC INTELLECTUAL PROPERTY MANAGEMENT CO., LTD., Osaka (JP)

(72) Inventor: Wataru SHINOHARA, Gifu (JP)

(21) Appl. No.: 14/527,516

(22) Filed: Oct. 29, 2014

Related U.S. Application Data
(63) Continuation of application No. PCT/JP2013/001215, filed on Feb. 28, 2013.

(30) Foreign Application Priority Data
May 30, 2012 (JP) 2012-123304

(51) Int. Cl. H01L 31/048; H01L 31/02; H01L 31/075; H01L 31/0216

(52) U.S. Cl. CPC H01L 31/0488; H01L 31/02168; H01L 31/02013; H01L 31/075
USPC 136/251

(57) ABSTRACT

The present disclosure improves photoelectric conversion efficiency in a photovoltaic device. This photoelectric conversion device is provided with: a first glass plate; a photoelectric conversion unit, which is fixed onto the first glass plate, and which generates power corresponding to input of light; and a second glass plate, which is disposed to cover the photoelectric conversion unit. In the photoelectric conversion device, at least a part of the periphery of the first glass plate and that of the second glass plate are melted and bonded to each other, and the photoelectric conversion unit has a plurality of photoelectric conversion elements connected in series or parallel.

### CROSS-REFERENCE TO RELATED APPLICATION

The present application is a continuation under 35 U.S.C. §120 of PCT/JP2013/001215, filed on Feb. 28, 2013, which is incorporated herein by reference and which claimed priority to Japanese Patent Application No. 2012-123304 filed on May 30, 2012. The present application likewise claims priority under 35 U.S.C. §119 to Japanese Patent Application No. 2012-123304 filed on May 30, 2012, the entire content of which is also incorporated herein by reference.

### TECHNICAL FIELD

The present disclosure relates to a photoelectric conversion device.

### BACKGROUND ART

As a power generation system using sunlight, a photoelectric conversion panel in which semiconductor thin films of amorphous, microcrystal or the like are laminated is used. In applying such a photoelectric conversion panel to a solar photovoltaic system, it is installed as a photoelectric conversion device (module) which is equipped with a module frame member in an outer periphery part of the device.

FIG. 12 to FIG. 14 show structure examples generally used in the photoelectric conversion device (module). FIG. 12 shows a super straight structure used in a solar battery such as a thin film silicon solar battery, and FIG. 13 shows a super straight structure used in a single-crystalline or polycrystalline silicon solar battery. In this structure, a photoelectric conversion panel 100 is sealed by a glass plate (glass substrate) 10 and a sealing member 12, and furthermore, a back sheet 14 having a metal thin film for preventing ingression of moisture or the like during outdoor use is superposed on the sealing member 12 side. Further, an end surface seal 16 for preventing ingress of moisture or the like from an end surface and breakage is provided for an outer periphery of the photoelectric conversion panel 100, and the outside of the seal is reinforced by a module frame member 18.

FIG. 14 shows an example of a glass package structure. In this structure, the above-described back sheet 14 is replaced with a glass plate 20, and an end surface seal 22 is filled between the glass plate 10 on a front surface side and the glass plate 20 on a rear surface side at an end part of the photoelectric conversion panel 100 to prevent ingression of moisture or the like.

On the other hand, a technique of welding glasses plates by irradiating laser beam having a pulse width of femtoseconds was disclosed.

In the super straight structure, there is a risk of ingress of moisture or the like into the back sheet 14 and the sealing member 12 permeating them if outdoor use of the structure continues for a long period of time. Further, there is also a risk of the occurrence of output reduction, failure such as disconnection, and changes in external appearance such as peeling of film due to ingress of moisture or the like from an end surface. Moreover, property improvement of a sealing member becomes necessary in order to improved long-term reliability, and a use amount of the member also increases, which could cause an increase in cost.

Further, it is difficult for the glass package structure to prevent ingress of moisture or the like from the end surface, and special end surface seal needs to be used, which incurs an increase in cost. Further, in a structure which does not use the module frame member 18, relative positions of the glass plate 10 and the glass plate 20 could be misaligned due to softening of the sealing member 12 during high temperature in summer.

Moreover, on a rear surface side of the photoelectric conversion elements which are formed on a front surface side on the glass plate 10, power-collecting wiring for collecting power or for extracting power outside the photoelectric conversion device, an insulative coating material for insulating the power-collecting wiring from rear surface electrodes of the photoelectric conversion elements, and the like are disposed, and a gap is generated between the glass plate 10 on a front surface side and the glass plate 20 on a rear surface side. If air is left in the gap, expansion/contraction of air occurs due to irradiation of sunlight or the like, and there is a risk of breakage of the glass plates 10, 20, ingress of water via the gap, or the like.

On the other hand, when the glass plate 10 and the glass plate 20 are pressure-bonded to make the gap smaller, stress is applied to the glass plate 20 by protrusions of a structure body on the rear surface of the photoelectric conversion elements, which could cause breakage.

### SUMMARY OF THE INVENTION

One aspect of the present disclosure is a photoelectric conversion device which is provided with: a first glass plate; a photoelectric conversion unit which is fixed on the first glass plate and generates power according to an input of light; and a second glass plate which is disposed so as to cover the photoelectric conversion unit, in which at least a part of the periphery of the second glass plate and that of the first glass plate are melted and bonded to each other, and a plurality of photoelectric conversion elements are connected in series or parallel in the photoelectric conversion unit.

### BRIEF DESCRIPTION OF THE DRAWINGS

FIG. 1 is a plan view showing a constitution of a photoelectric conversion device in a first embodiment of the present disclosure.

FIG. 2 is a cross-sectional view showing the constitution of the photoelectric conversion device in the first embodiment of the present disclosure.

FIG. 3 is a cross-sectional view showing another example of the constitution of the photoelectric conversion device in the first embodiment of the present disclosure.

FIG. 4 is a plan view showing another example of the constitution of the photoelectric conversion device in the first embodiment of the present disclosure.

FIG. 5 is a cross-sectional view showing another example of the constitution of the photoelectric conversion device in the first embodiment of the present disclosure.

FIG. 6 is a view for explaining a manufacturing method of the photoelectric conversion device in the first embodiment of the present disclosure.

FIG. 7 is a cross-sectional view showing another example of the constitution of the photoelectric conversion device in the first embodiment of the present disclosure.

FIG. 8 is a cross-sectional view showing another example of the constitution of the photoelectric conversion device in the first embodiment of the present disclosure.

FIG. 9 is a plan view showing another example of the constitution of the photoelectric conversion device in the first embodiment of the present disclosure.

FIG. 10 is a cross-sectional view showing another example of the constitution of the photoelectric conversion device in the first embodiment of the present disclosure.

FIG. 11 is a plan view showing another example of the constitution of the photoelectric conversion device in the first embodiment of the present disclosure.

FIG. 12 is a cross-sectional view showing another example of a constitution of a conventional photoelectric conversion device.

FIG. 13 is a cross-sectional view showing another example of the constitution of the conventional photoelectric conversion device.

FIG. 14 is a cross-sectional view showing another example of the constitution of the conventional photoelectric conversion device.

FIG. 15 is a plan view showing another example of the constitution of the photoelectric conversion device in the first embodiment of the present disclosure.

FIG. 16 is a cross-sectional view showing another example of the constitution of the photoelectric conversion device in the first embodiment of the present disclosure.

FIG. 17 is a cross-sectional view showing a constitution of a photoelectric conversion device in a second embodiment of the present disclosure.

FIG. 18 is a cross-sectional view showing another example of the constitution of the photoelectric conversion device in the second embodiment of the present disclosure.

FIG. 19 is a cross-sectional view showing another example of the constitution of the photoelectric conversion device in the second embodiment of the present disclosure.

FIG. 20 is a view for explaining a manufacturing method of a photoelectric conversion device in a third embodiment of the present disclosure.

FIG. 21 is a view for explaining a manufacturing method of the photoelectric conversion device in the third embodiment of the present disclosure.

FIG. 22 is a plan view showing a constitution of a photoelectric conversion device in a fourth embodiment of the present disclosure.

FIG. 23 is a cross-sectional view showing the constitution of the photoelectric conversion device in the fourth embodiment of the present disclosure.

FIG. 24 is a plan view and a cross-sectional view showing the constitution of the photoelectric conversion device in the fourth embodiment of the present disclosure.

FIG. 25 is a cross-sectional view showing a constitution of a photoelectric conversion device in a fifth embodiment of the present disclosure.

FIG. 26 is a plan view showing a constitution of photoelectric conversion device in a sixth embodiment of the present disclosure.

FIG. 27 is a cross-sectional view showing a constitution of a current extraction part in the sixth embodiment the present disclosure.

### DESCRIPTION OF THE PREFERRED EMBODIMENTS

<Basic Constitution>

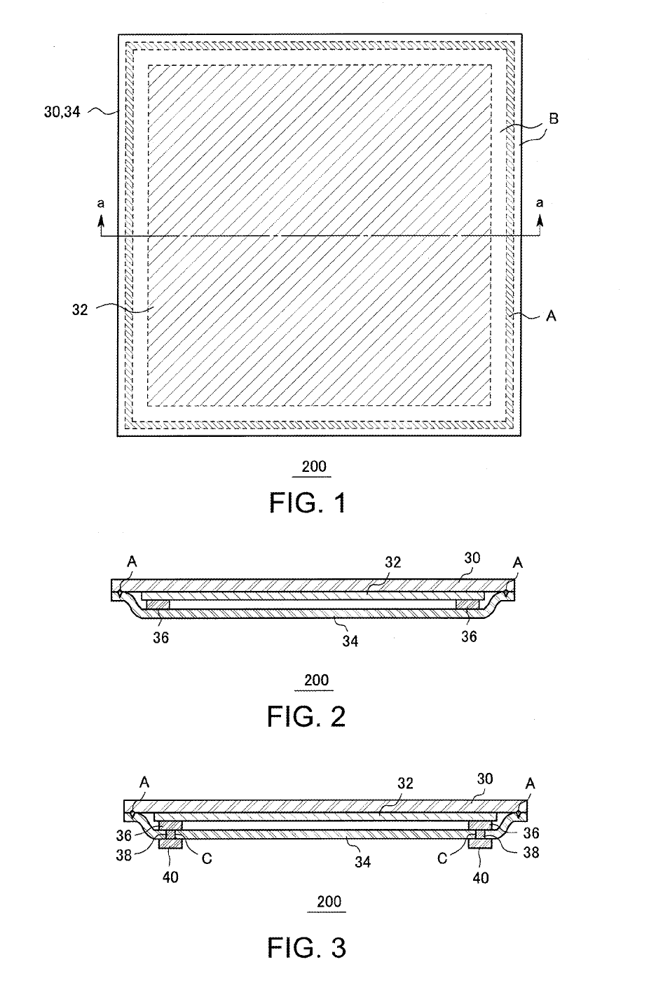

A photoelectric conversion device 200 in the first embodiment of the present disclosure is constituted by including a front surface glass plate (glass substrate) 30, a photoelectric conversion unit 32, and a rear surface glass plate 34 as shown in the external appearance plan view of FIG. 1 and the cross-sectional view of FIG. 2. The photoelectric conversion device 200 shows an example applied to a thin film silicon solar battery module. It should be noted that FIG. 2 is a cross-sectional view taken along line a-a of FIG. 1. In FIG. 2, thickness of each constituent part is expressed in a ratio different from actual thickness in order to clearly show each constituent part of the photoelectric conversion device 200.

As the front surface glass plate 30, a glass plate of 1 m square and 4 mm thickness is applied for example. However, the invention is not limited to this, but may be any plate which is suitable for forming the photoelectric conversion unit 32 and capable of mechanically supporting the photoelectric conversion device 200. Input of light to the photoelectric conversion device 200 is performed basically from the front surface glass plate 30 side.

The photoelectric conversion unit 32 is formed on the front surface glass plate 30. The photoelectric conversion unit 32 is formed by laminating a transparent electrode, a photoelectric conversion unit, a rear surface electrode and the like. As the transparent electrode, a film formed by combining at least one type or plural types out of transparent conductive oxide (TCO) in which tin (Sn), antimony (Sb), fluorine (F), aluminum (Al) or the like is doped with tin oxide (SnO₂), zinc oxide (ZnO), indium tin oxide (ITO) or the like, for example, can be used. Further, the photoelectric conversion unit should be an amorphous silicon photoelectric conversion unit (a-Si unit), a microcrystal silicon photoelectric conversion unit (μc-Si unit) or the like, for example. The photoelectric conversion unit may have a structure in which a plurality of the photoelectric conversion units are laminated such as a tandem type and a triple type. The rear surface electrode may be the transparent conductive oxide (TCO) reflective metal, or a laminated structure thereof. Tin oxide (SnO₂), zinc oxide (ZnO), indium tin oxide (ITO) or the like is used as the transparent conductive oxide (TCO), and metal such as silver (Ag) and aluminum (Al) is used as the reflective metal.

The rear surface glass plate 34 is provided so as to cover the photoelectric conversion unit 32 formed on the front surface glass plate 30. The rear surface glass plate 34 has substantially the same size as the front surface glass plate 30 for example, and a glass plate having the thickness of 2 mm is applied. However, the plate is not limited to this.

The front surface glass plate 30 and the rear surface glass plate 34 are melted and bonded in a bonding region A of their outer peripheral regions. The bonding region A is provided for peripheral part B where the photoelectric conversion unit 32 is not formed in the front surface glass plate 30. The peripheral part B (region not hatched in FIG. 1) can be provided by removing the photoelectric conversion unit 32, which was formed once on the front surface glass plate 30, by laser or the like for example. To melt and bond the front surface glass plate 30 and the rear surface glass plate 34, it is preferred to make the peripheral part of at least one of the front surface glass plate 30 and the rear surface glass plate 34 have a bent state as shown in FIG. 2.

It should be noted that the photoelectric conversion device 200 may be provided with interconnectors 36 for extracting power generated in the photoelectric conversion unit 32 to the outside. Herein, the film thickness of the photoelectric conversion unit 32 is several μm and the thickness of the interconnectors 36 is approximately several hundred μm, so that when the width of the peripheral part B is approximately 10 mm, the four outer peripheral sides are completely adhered by elastic deformation of either the front surface glass plate 30 or the rear surface glass plate 34, and the plates can be melted and bonded in the bonding region A.

The cross-sectional view in FIG. 3 shows a configuration example of extracting generated electric power via the interconnectors 36. In the configuration example, openings C are provided for predetermined positions of the rear surface glass plate 34, and wiring cords 38 being current paths are allowed to pass through the openings. Moreover, terminal boxes 40 are disposed at positions overlapping the openings C, and the wiring cords 38 are connected to the terminal boxes 40. In this way, the openings C are covered by the terminal boxes 40, and generated electric power can be extracted to the outside without impairing a sealing effect. It should be noted that the inside of the terminal boxes 40 may be filled with butyl resin or the like to make sealing more secure. Further, the openings C may be provided for the front surface glass plate 30 side.

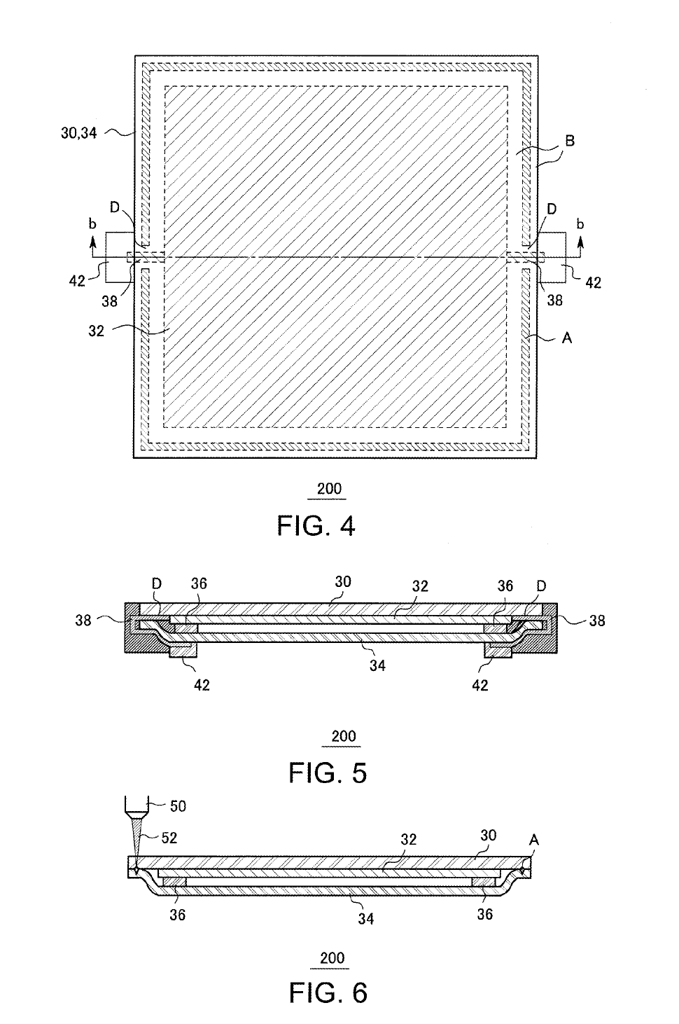

Further, the plan view in FIG. 4 and the cross-sectional view in FIG. 5 show another configuration example for extracting generated electric power. FIG. 5 shows a cross section taken along line b-b of FIG. 4. In this example, the bonding region A is not provided for a part of the outer periphery of the front surface glass plate 30 and the rear surface glass plate 34 but openings D are formed. The wiring cords 38 being a current path are allowed to go through the openings D, and only these portions are sealed by end surface seal members 42. Portions sealed by the end surface seal members 42 are likely to be an ingress route for moisture or the like from the external environment, but reliability of the photoelectric conversion device 200 can be improved by making the regions shorter than a conventional structure.

<Melting and Bonding Method>

FIG. 6 shows a method for melting and bonding the front surface glass plate 30 and the rear surface glass plate 34 in the photoelectric conversion device 200 in the bonding region A.

As shown in FIG. 2, a peripheral part of at least one of the front surface glass plate 30 and the rear surface glass plate 34 is bent to make the peripheral part B of the front surface glass plate 30 and the rear surface glass plate 34 be an adhered state. Then, a laser beam 52 is irradiated from a laser device 50 focusing on a contact surface of the adhered peripheral part B, and is scanned along the outer peripheral four sides of the front surface glass plate 30 and the rear surface glass plate 34.

It is preferred that the laser beam 52 be femtosecond laser beam. Specifically, it is preferred that the laser beam 52 have a pulse width of 1 nanosecond or less. Further, it is preferred that the laser beam 52 have a wavelength at which adsorption occurs on at least one of the front surface glass plate 30 and the rear surface glass plate 34. For example, it is preferred that the laser beam 52 have a wavelength of 800 nm. Moreover, it is preferred that the laser beam 52 irradiate at sufficient energy density and scanning speed as to melt the front surface glass plate 30 and the rear surface glass plate 34. For example, it is preferred that the laser beam 52 irradiate at pulse energy of 10 micro-joule (μJ) per one pulse. Further, it is preferred to scan the laser beam 52 at a scanning speed of 60 mm/minute. Further, the laser beam 52 may irradiate either from the front surface glass plate 30 side or the rear surface glass plate 34 side.

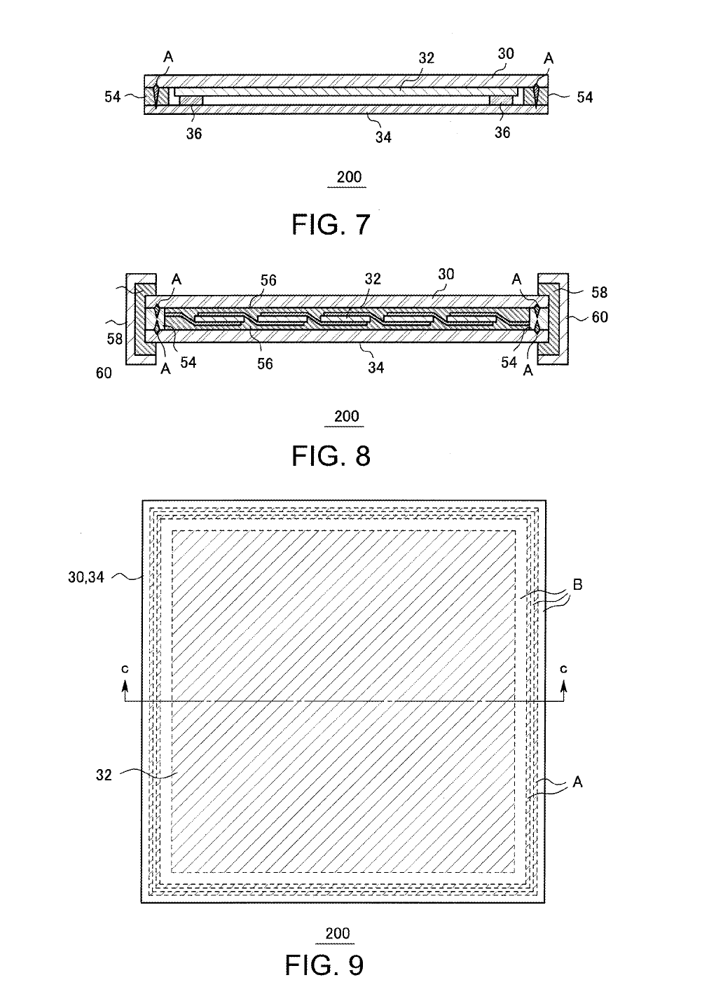

Now, in the case where the thickness of the photoelectric conversion unit 32 and the interconnectors 36 is large and a gap between the peripheral part of the front surface glass plate 30 and the rear surface glass plate 34 becomes larger, filler 54 may be filled in the gap, and the filler 54 is melted to melt and bond the front surface glass plate 30 and the rear surface glass plate 34 as shown in the cross-sectional view in FIG. 7.

As the filler 54, it is preferred to apply a material including an element which is capable of melting and bonding the front surface glass plate 30 and the rear surface glass plate 34 such as Si, SiO, SiO₂ and SiOₓ.

Further, the laser beam 52 can irradiate either from the front surface glass plate 30 side or the rear surface glass plate 34 side, so that in the case where the photoelectric conversion unit 32 (including silicon substrate) itself is thick like a crystalline silicon solar battery, a constitution in which the front surface of the filler 54 is melted and bonded with the front surface glass plate 30 and the rear surface of the filler 54 is melted and bonded with the rear surface glass plate 34 is acceptable as shown in FIG. 8.

In such a case, a conventional sealing member 56 may be used in combination in order to planarize unevenness caused by the photoelectric conversion unit 32. Further, in order to further increase a sealing effect, a conventional end surface seal 58 and a conventional frame 60 may be used in combination.

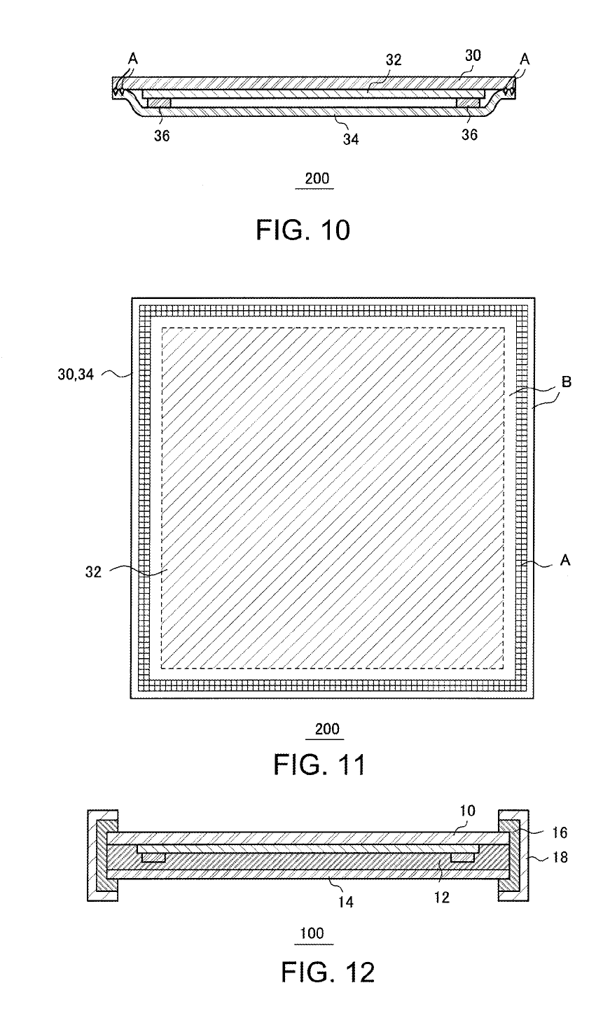

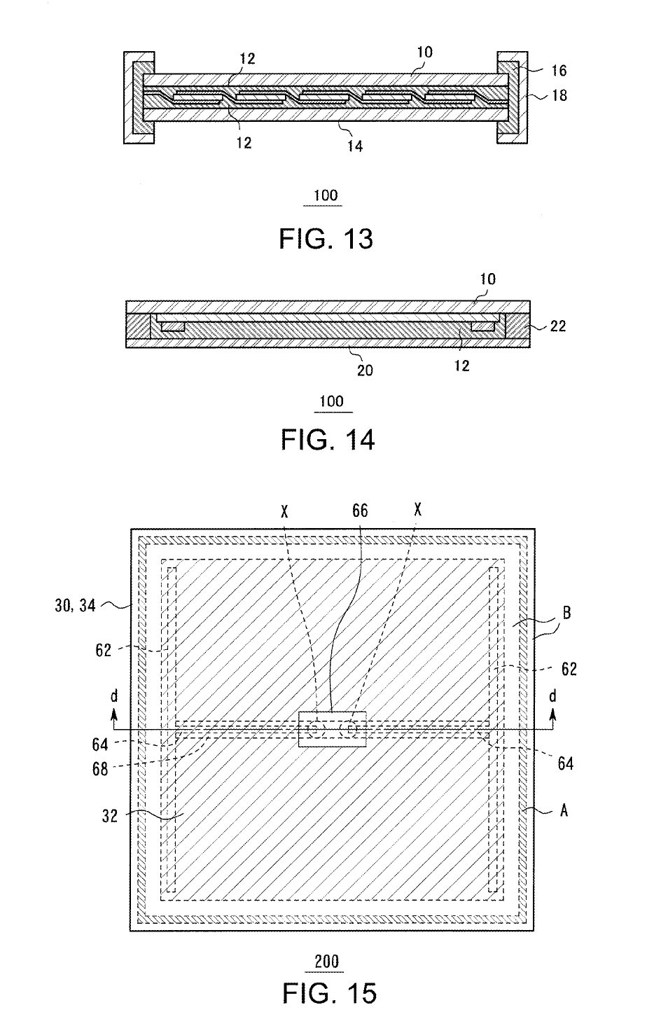

Further, the bonding region A does not need to be a single line, and a plurality of the bonding regions A may be provided, as shown in the plan view in FIG. 9 and the cross-sectional view in FIG. 10. As shown in FIG. 9 and FIG. 10, by providing a plurality of the bonding regions A in parallel, bonding strength and airtightness of the front surface glass plate 30 and the rear surface glass plate 34 can be further improved. Moreover, as shown in FIG. 11, the bonding region A may be provided in a lattice shape. Thus, bonding strength and airtightness can be further improved. It should be noted that FIG. 11 shows the bonding region A in lines.

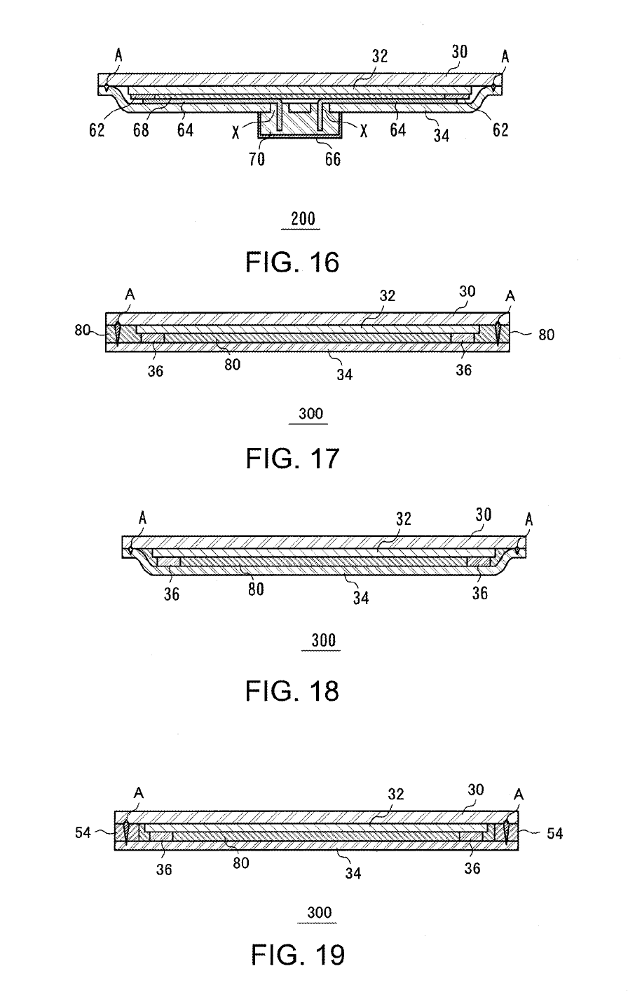

The plan view in FIG. 15 and the cross-sectional view in FIG. 16 show another configuration example for extracting generated electric power. FIG. 16 shows the cross section taken along line d-d in FIG. 15. In the configuration example, first power-collecting wirings 62 and second power-collecting wirings 64 are formed for extracting power generated in the photoelectric conversion unit 32. The first power-collecting wirings 62 are wirings for collecting power from the plurality of photoelectric conversion units 32, and the second power-collecting wirings 64 are wirings which connect the first power-collect ing wirings 62 to a terminal box 66. It should be noted that the photoelectric conversion units 32 may be connected not in parallel directions but in serial directions. In this case, solar battery cells divided in serial directions are connected in series by the transparent electrode and the rear surface electrode.

The first power-collecting wirings 62 are provided on the rear surface electrode of the photoelectric conversion units 32 in an extending manner. The first power-collecting wirings 62 are formed to connect positive electrodes and negative electrodes of a photoelectric conversion layer which is divided in a parallel manner near end sides of the photoelectric conversion device 200. Therefore, the first power-collecting wirings 62 are provided in an extending manner along a direction orthogonal to a parallel divided direction of the photoelectric conversion layer. In the configuration example, the first power collecting wirings 62 are provided in an extending manner in vertical directions along end sides on right and left as shown in FIG. 15. Thus, positive electrodes and negative electrodes of the photoelectric conversion unit 32 which are connected in series are connected in parallel.

Next, an insulating coating material 68 is arranged in order to form electrical insulation between the second power-collecting wirings 64 and the rear surface electrode. The insulating coating material 68 is provided in an extending manner on the rear surface electrode of the photoelectric conversion unit 32 from the vicinity of the first power-collecting wirings 62, which are provided along the end sides on right and left of the photoelectric conversion device 200, to a disposed position of the terminal box 66 at the central part, as shown in FIG. 15 and FIG. 16. Herein, as shown in FIG. 15, the insulating coating material 68 is provided in an extending manner along lateral directions from the vicinity of the first power-collecting wirings 62 on the right and left toward the terminal box 66. It is preferred that the insulating coating material 68 be polyester (PE), polyethylene terephthalate (PET), polyethylene naphthalate (PEN), polyimide, polyvinyl fluoride or the like for example. Further, as the insulating coating material 68, it is preferred to use a material on the rear surface of which adhesive agent is coated in a sealed state.

The second power-collecting wirings 64 are provided in an extending manner from areas on the first power-collecting wirings on the right and left toward the central part of the photoelectric conversion device 200 along an area on the insulating coating material 68, as shown in FIG. 15 and FIG. 16. The insulating coating material 68 is sandwiched between the second power-collecting wirings 64 and the rear surface electrode of the photoelectric conversion units 32, and electrical insulation between the second power-collecting wirings 64 and the rear surface electrode is maintained. On the other hand, one end of each of the second power-collecting wirings 64 is provided in an extending manner onto the first power-collecting wiring 62, and electrically connected to the first power-collecting wiring 62. For example, it is preferred to electrically connect the second power-collecting wirings 64 to the first power-collecting wirings 62 by ultrasonic soldering or the like. The other end of each of the second power-collecting wirings 64 is connected to electrode terminals in the terminal box 66 (described later).

The rear surface of the photoelectric conversion device 200 is sealed by the rear surface glass plate 34. At this point, end part of the second power-collecting wirings 64 are pulled out through holes X provided near the attaching position of the terminal box 66 on the rear surface glass plate 34. Then, the end part of each of the second power-collecting wirings 64 is electrically connected to terminal electrodes in the terminal box 66 by soldering or the like, insulating resin 70 such as silicon is filled into a space in the terminal box 66, and the box is closed with a lid. It is preferred to attach the terminal box 66 in the vicinity of the holes X, which are used for pulling out the end part of each of the second power-collecting wirings 64, by adhering using silicon or the like.

The front surface glass plate 30 and the rear surface glass plate 34 are melted and bonded in the bonding region A of their outer peripheral regions. The bonding region A is provided for the peripheral part B where the photoelectric conversion unit 32 is not formed in the front surface glass plate 30. The peripheral part B (a region not hatched in FIG. 1) can be provided by removing the photoelectric conversion unit 32 which was formed once on the front surface glass plate 30 by laser or the like, for example. To melt and bond the front surface glass plate 30 and the rear surface glass plate 34, it is preferred to make a peripheral part of at least one of the front surface glass plate 30 and the rear surface glass plate 34 be a bent state as shown in FIG. 16.

### Second Embodiment

A photoelectric conversion device 300 in the second embodiment is constituted by including a sealing member 80 in addition to the front surface glass plate 30, the photoelectric conversion unit 32, and the rear surface glass plate 34 as shown in the cross-sectional view in FIG. 17. FIG. 17 expresses the thickness of each constituent part in a ratio different from the actual thickness to clearly show each constituent part of the photoelectric conversion device 300.

In the photoelectric conversion device 300, before covering the photoelectric conversion unit 32 by the rear surface glass plate 34, the sealing member 80 is coated on the rear surface of the photoelectric conversion unit 32, and covered by the rear surface glass plate 34 after baking.

Herein, it is preferred that the sealing member 80 be a material having a rate of thermal expansion closer to that of the front surface glass plate 30 and the rear surface glass plate 34, and it is preferred to use a silicon oxide based material. It is preferable that the silicon oxide-based material be a material containing SiC, SiO₂ or SiO, by at least 50% or more as a main component. By using a silicon oxide-based material as the sealing member 80, coefficients of thermal expansion the front surface glass plate 30 and the rear surface glass plate 34 can be made closer, and occurrence of thermal stress between the front surface glass plate 30, the rear surface glass plate 34 and the sealing member 80, which arises from heating by sunlight irradiation or the like, can be suppressed. Therefore, breakage of the front surface glass plate 30, the rear surface glass plate 34 and the sealing member 80 caused by thermal stress can be prevented.

For example, silica sol (silica gel) which is formed by mixing microparticles of silicon oxide (glass) into a binder of resin such as acrylic resin or solvent such as water and organic solvent is coated by a spray coating method, a spin coater coating method or the like. Then, the sealing member 80 is solidified by heating at several tens of ° C. to several hundred ° C., covered by the rear surface glass plate 34, and the front surface glass plate 30 and the rear surface glass plate 34 are bonded.

As described, at least a part of a gap which occurs close to power collecting wirings, an insulating coating material or the like between the front surface glass plate 30 and the rear surface glass plate 34 is buried by the silicon oxide-based sealing member 80. In this way, air in the gap which occurs between the front surface glass plate 30 and the rear surface glass plate 34 is eliminated, any effect due to expansion/contraction of air can be reduced, and breakage of the front surface glass plate 30 or the rear surface glass plate 34 can be suppressed. Further, ingress of water via the gap between the front surface glass plate 30 and the rear surface glass plate 34 can be prevented.

FIG. 17 is one example of the photoelectric conversion device 300 in the second embodiment. This example has a structure in which the sealing member 80 is coated on the entire surface of a side of the front surface glass plate 30 on which the photoelectric conversion unit 32 is formed. In this case, after covering with the rear surface glass plate 34, the front surface of the sealing member 80 in the outer periphery portion of the photoelectric conversion device 300 and the front surface glass plate 30 may be melted and bonded, and the rear surface of the sealing member 80 and the rear surface glass plate 34 may be melted and bonded.

With such a structure, the front surface glass plate 30 and the rear surface glass plate 34 can be melted and bonded without widely bending both plates. Therefore, bending stress applied to the front surface glass plate 30 and the rear surface glass plate 34 can be made smaller, and breakage of the front surface glass plate 30 or the rear surface glass plate 34 can be suppressed.

FIG. 18 is another example of the photoelectric conversion device 300 in the second embodiment. This example has a structure in which the sealing member 80 is coated leaving an outer periphery portion of the front surface glass plate 30 on a side on which the photoelectric conversion unit 32 is formed. In this case, after covering with the rear surface glass plate, the front surface glass plate 30 and the rear surface glass plate 34 are melted and bonded in a state where a peripheral part of at least one of the front surface glass plate 30 and the rear surface glass plate 34 is bent. It is preferred that the bonding region be a peripheral part in the front surface glass plate 30 where the photoelectric conversion unit 32 is not formed.

In this case, since the front surface glass plate 30 and the rear surface glass plate 34 are directly melted and bonded, bonding force can be increased. Further, glass plates are pressed against each other by bending of the front surface glass plate 30 or the rear surface glass plate 34, and adhesion property of the front surface glass plate 30 and the rear surface glass plate 34 can be improved. In this way, air between the front surface glass plate 30 and the rear surface glass plate 34 can be eliminated even more efficiently, which enhances an effect of suppressing breakage of the front surface glass plate 30 or the rear surface glass plate 34 caused by expansion/contraction of air. Further, ingress of water via the gap between the front surface glass plate 30 and the rear surface glass plate 34 can be also reduced more.

It should be noted that the structures of FIG. 17 and FIG. 18 can be applied to a structure in which the wiring cords 38 are extracted from the openings D of the peripheral part such as a photoelectric conversion device 100 shown in FIG. 5. In this case, a constitution in which the openings D are simultaneously sealed by the sealing member 80 by coating the sealing member 80 on the regions of the openings D is acceptable.

FIG. 19 is another example of the photoelectric conversion device 300 in the second embodiment. This example has a structure in which the sealing member 80 is coated leaving the outer periphery portion of the front surface glass plate 30 on the side on which the photoelectric conversion unit 32 is formed, the filler 54 is filled between the front surface glass plate 30 and the rear surface glass plate 34, and the filler 54 is melted to melt and bond the front surface glass plate 30 and the rear surface glass plate 34.

Even with this structure, similarly to the example in FIG. 17, bending stress applied to the front surface glass plate 30 and the rear surface glass plate 34 can be made smaller, and breakage of the front surface glass plate 30 or the rear surface glass plate 34 can be suppressed. The constitution in which the filler 54 and the sealing member 80 are used in combination can also be applied to a module of the thick photoelectric conversion unit 32 such as the crystalline silicon solar battery shown in FIG. 8.

Further, in the examples in FIG. 18 and FIG. 19, it is also preferred to perform treatment of covering by the rear surface glass plate 34 before completely solidifying the sealing member 80. By performing sealing in a state where fluidity of the sealing member 80 is high, filling factor of the sealing member 80 in a gap between the front surface glass plate 30 and the rear surface glass plate 34 in the peripheral part or a gap formed by the filler 54 and the sealing member 80 can be further improved.

Now, a similar effect can be obtained by treatment in which the sealing member 80 is completely solidified in a region other than the peripheral part of the photoelectric conversion device 300, then the sealing member 80 is newly coated on the peripheral part only, and covered by the rear surface glass plate 34 in a state where the material is not completely solidified.

### Third Embodiment

A photoelectric conversion device 400 in a third embodiment has a constitution similar to the photoelectric conversion device 100 in the first embodiment, in which air in the gap between the front surface glass plate 30 and the rear surface glass plate 34 is discharged into a decompressed state to the atmospheric.

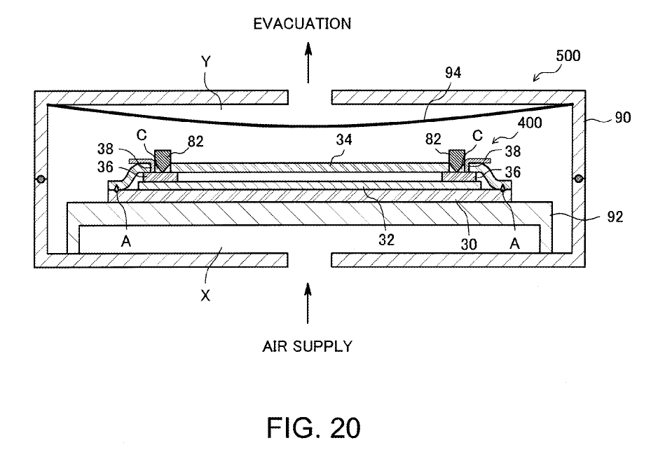

FIG. 20 shows a laminating device 500 for the photoelectric conversion device 400. The laminating device 500 is constituted by including a chamber 90, a heater 92 and a diaphragm 94. The laminating device 500 has a structure in which an upper region Y and a lower region X of the chamber 90 are partitioned by the elastic diaphragm 94. Further, the lower region X of the chamber 90 is provided with the heater 92 which is mounted on and heats the photoelectric conversion device 400.

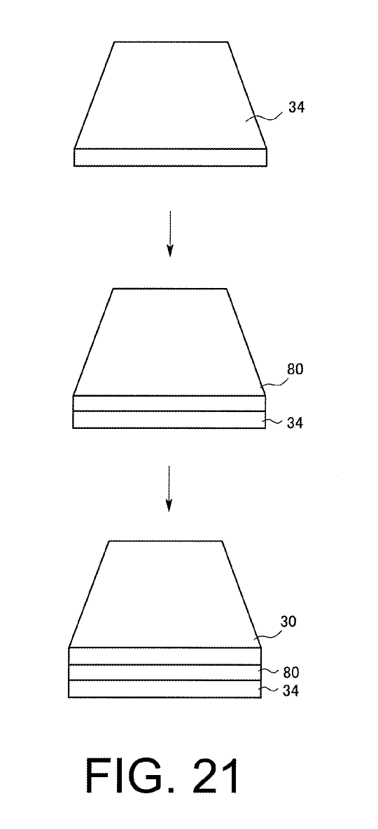

In laminating the photoelectric conversion device 400, after the front surface glass plate 30 and the rear surface glass plate 34 are melted and bonded in the bonding region A as shown in FIG. 20, the device is installed on the heater 92 in a state where sealing members 82 are disposed in the openings C of the wiring cords 38 of the interconnectors 36. It is preferred that the sealing members 82 be butyl resin for example. At this point, air or the like is supplied to the lower region X of the chamber 90, and the photoelectric conversion device 400 is installed on the heater 92 in a state where the diaphragm 94 is pulled upward by evacuating the upper region Y. Then, while the photoelectric conversion device 400 is being heated by the heater 92, the lower region X of the laminating device 500 is evacuated as shown in FIG. 21, and the sealing members 82 are pressed against the openings C by the diaphragm 94 by supplying air to the upper region Y. In this way, the sealing members 82 softened by heating are pressed against the openings C, the sealing members 82 are deformed into the shape of the openings C, and the openings C are sealed.

At this point, air collected in the gap between the front surface glass plate 30 and the rear surface glass plate 34 is simultaneously exhausted from the openings C, and the openings are sealed in a state where pressure in the gap between the front surface glass plate 30 and the rear surface glass plate 34 is decompressed more than atmospheric pressure.

As described, air in the gap, which occurs because of the power-collecting wiring, the insulating coating material or the like between the front surface glass plate 30, and the rear surface glass plate 34, can be exhausted. In this way, affect of expansion/contraction of air in the gap between the front surface glass plate 30 and the rear surface glass plate 34 can be reduced, and breakage of the front surface glass plate 30 or the rear surface glass plate 34 can be suppressed. Further, ingress of water via the gap between the front surface glass plate 30 and the rear surface glass plate 34 can be prevented.

It should be noted that the constitution in which sealing is performed in the state where air between the front surface glass plate 30 and the rear surface glass plate 34 is exhausted can be similarly applied in the constitution shown in FIG. 4 in which the wiring cords 38 are pulled out from the peripheral part of the photoelectric conversion device or the constitution shown in FIG. 15 in which the wiring cords 38 are pulled out from the central part of the photoelectric conversion device as well.

Further, in the third embodiment, air between the front surface glass plate 30 and the rear surface glass plate 34 is exhausted from the openings C for pulling out the wiring cords 38 to the outside, and the openings C are sealed in the exhausted state, but the invention is not limited to this. A constitution in which openings other than the openings for pulling out the wiring cords 38 are provided for the photoelectric conversion device, air between the front surface glass plate 30 and the rear surface glass plate 34 is exhausted from the openings, and the openings are sealed by the sealing members 82, is also acceptable.

### Fourth Embodiment

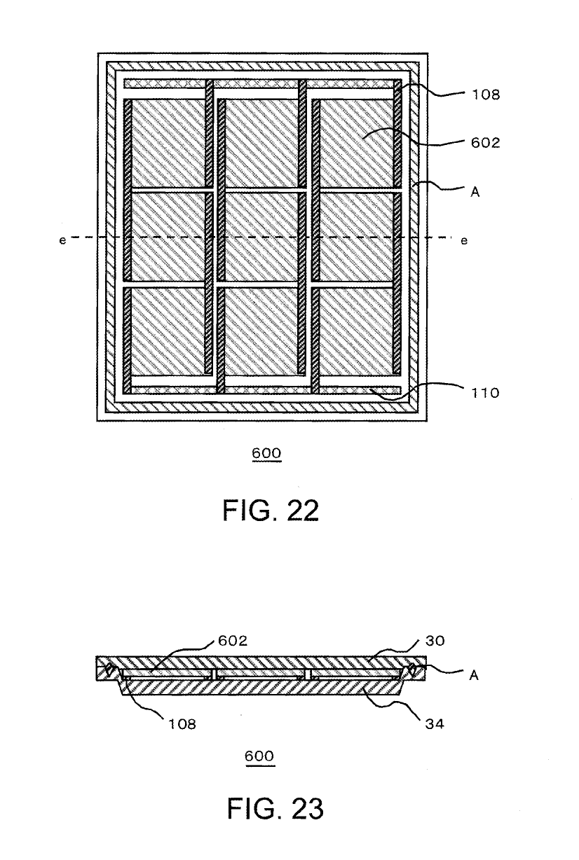

A photoelectric conversion device 600 in the fourth embodiment of the present disclosure is constituted by including the front surface glass plate 30, photoelectric conversion units 602, and the rear surface glass plate 34 as shown in the external appearance plan view in FIG. 22 and the cross-sectional view in FIG. 23. In this embodiment as well, at least a part of the front surface glass plate 30 and that of the rear surface glass plate 34 are melted and bonded to each other in the bonding region A. It should be noted that FIG. 23 is a cross-sectional view taken along line e-e FIG. 22.

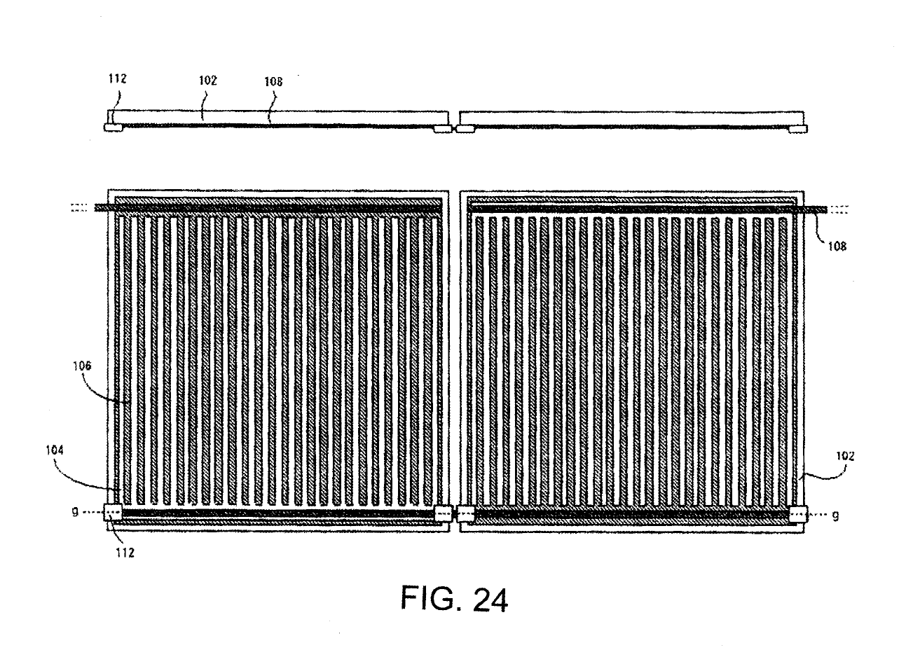

The photoelectric conversion element is a rear surface bonding photoelectric conversion element in which both of a positive side electrode 104 and a negative side electrode 106 are provided on a rear surface side being the opposite side of the light receiving surface, as shown in the plan view seen from the rear surface side being the opposite side of the light receiving surface in FIG. 24. It should be noted that the comb-shaped positive side electrode 104 is not hatched and the negative side electrode 106 is hatched in FIG. 24, where the electrodes are combined with each other, to facilitate understanding. As shown in the front and side views in FIG. 24, in this embodiment, three photoelectric conversion elements are installed so as to face in opposite directions to each other on the front surface glass plate 30, and electrically connected in series by serial interconnectors 108. Moreover, the elements are connected in parallel by parallel interconnectors 110 at both ends of the photoelectric conversion device (top and bottom ends in FIG. 22). A plurality of photoelectric conversion elements are connected in series or parallel and the photoelectric conversion unit 602 is constituted in this manner.

The serial interconnectors 108 are electrically connected severally to the positive side electrode 104 and the negative side electrode 106 at both ends of a photoelectric conversion unit 102 (right and left ends in FIG. 24), and connect the positive side electrode 104 and the negative side electrode 106 of adjacent photoelectric conversion units 102 in series. The parallel interconnectors 110 electrically connect the serial interconnectors 108 connected to the positive side electrode 104 or the serial interconnectors 108 connected to the negative side electrode 106 in parallel severally outside the photoelectric conversion units 102 (top and bottom ends in FIG. 24). Ribbon-shaped copper foil is coated by solder on the serial interconnectors 108, and as shown in the side view in FIG. 24, a constitution in which an insulating coating material 112 is applied to regions corresponding to the vicinity of the outer periphery of the photoelectric conversion element is acceptable. The serial interconnectors 108 are thermocompression-bonded to the positive side electrode 104 and the negative side electrode 106.

By having the constitution in which the photoelectric conversion elements are connected in series or parallel in this manner, voltage and current which are optimum for inputting a load or a power conditioner connected to the photoelectric conversion device 600 can be extracted. It should be noted that the photoelectric conversion element is not limited to the rear surface bonding photoelectric conversion element, but thin-film photoelectric conversion elements having at least a pair or PIN junctions may be connected in series or parallel for example.

### Fifth Embodiment

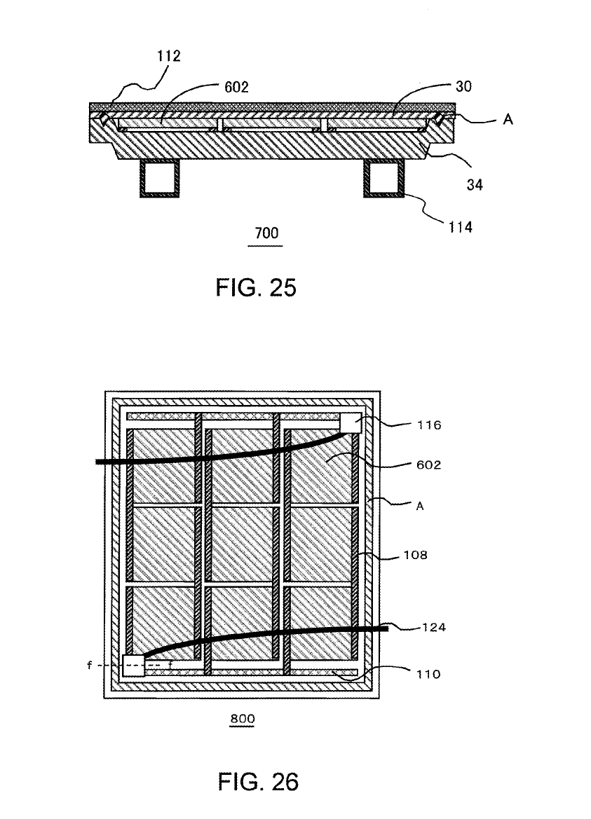

A photoelectric conversion device 700 in a fifth embodiment of the present disclosure is constituted by including low-refractive-index layer 112 on the front surface glass plate in addition to the front surface glass plate 30, the photoelectric conversion unit 602, and the rear surface glass plate 34 as shown in FIG. 25. In this embodiment as well, at least a part of the front surface glass plate 30 and that of the rear surface glass plate 34 are melted and bonded to each other in the bonding region A.

The front surface glass plate 30 is a tempered glass plate with a thickness of 1.8 mm, and which is fabricated by an air-cooling and tempering method. The front surface glass plate 30 has higher tolerance to damage caused by wind and rain in outdoor use compared to the non-tempered front surface glass plate 34.

As shown in FIG. 25, the thickness of the rear surface glass plate 34 is made thicker than the thickness of the front surface glass plate 30 in this embodiment. For example, the thickness of the rear surface glass plate 34 should be approximately 5.0 mm. In many cases, the device is installed by adhering metal attaching bases 114 to the rear surface glass plate 34 with adhesive agent or the like. In the case where external force caused by wind and rain is applied to the photoelectric conversion device 700, larger deformation occurs in the front surface glass plate 30 compared to the rear surface glass plate 34 adhered to the attaching bases 114. Therefore, the front surface glass plate 30 is prone to be broken easily. At this point, the thinner the thickness of the front surface glass plate 30 is, the smaller a deformation amount of the outermost surface can be made, so that breakage can be suppressed. It should be noted that the rear surface glass plate 34 may also be a tempered glass plate.

Further, the low-refractive-index layer 112 may be formed on the front surface glass plate 30 as shown in FIG. 25. The low-refractive-index layer 112 should be porous silicon oxide or the like, for example. Porous silicon oxide can be formed by coating sol-gel of a silica material such as TEOS (tetramethyl orthosilicate) on the front surface glass plate 30 and baking it. Since an average index of refraction of porous silicon oxide is 1.45, light reflection loss on a front surface of the front surface glass plate 30 with an index of refraction at 1.52 can be reduced.

### Sixth Embodiment

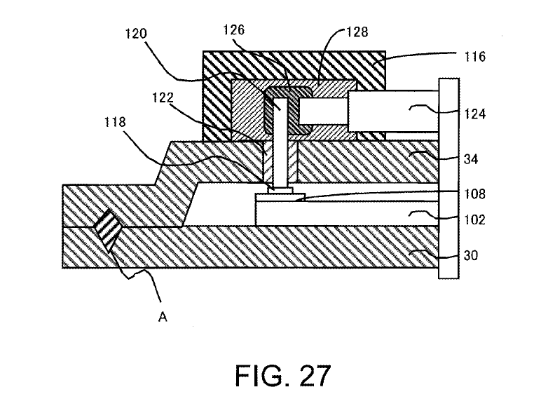

A photoelectric conversion device 800 in a sixth embodiment of the present disclosure is provided with terminal boxes 116 for extracting generated electric current on the rear surface glass plate 34 as shown in FIG. 26 in addition to the photoelectric conversion device 600 in the fourth embodiment. It should be noted that FIG. 26 is a plan view of a rear surface side being the opposite side of the light receiving surface of the photoelectric conversion device 800. FIG. 27 is a cross-sectional view taken along line f-f of FIG. 26. Further, in this embodiment as well, at least a part of the front surface glass plate 30 and the rear surface glass plate 34 is melted and bonded in the bonding region A.

A current extraction part of the photoelectric conversion device 800 consists of the serial interconnector 108, solder 118, a metal wire 120, and a low-melting-point glass 122. Firstly, the metal wire 120 is allowed to go through a through hole 34a provided for the rear surface glass plate 34, and a gap between the through hole 34a and the metal wire 120 is filled by the low-melting-point glass 122. In this way, extraction wiring for generated electric power through the rear surface glass plate 34 is formed by the metal wire 120, and the rear surface glass plate 34 is airtightly sealed by the low-melting-point glass 122. The metal wire 120 should be an alloy of iron and nickel in a ration of 50:50 for example. Such an alloy has a coefficient of thermal expansion relatively close to the coefficient of thermal expansion of the low-melting-point glass 122, and cracking caused by thermal expansion in airtight sealing can be suppressed. Then, tip of the metal wire 120 is connected to the serial interconnector 108 of the photoelectric conversion unit 602, which is disposed on the front surface glass plate 30, via the solder 118. The solder 118 is disposed for the tip of the serial interconnector 108 or the metal wire 120 in advance, and the serial interconnector 108 and the metal wire 120 can be connected by melting through heating the solder via the metal wire 120 exposed outside. Then, in this embodiment as well, at least a part of the front surface glass plate 30 and that of the rear surface glass plate 34 are melted and bonded to each other in the bonding region A.

The terminal box 116 includes a cable 124, solder 126 and insulating resin 128. The cable 124 is connected to the metal wire 120 by the solder 126. The terminal box 116 is adhered to the rear surface glass plate 34 by the insulating resin 128. The insulating resin 128 has a relatively high water vapor barrier property, but is likely to be affected by water vapor in the long run. However, if the structure of the current extraction part such as the photoelectric conversion device 800 is adopted, moisture ingress does not reach the photoelectric conversion element, and a highly airtight photoelectric conversion device can be obtained.

What is claimed is:

1. A photoelectric conversion device comprising:
a first glass plate;
a photoelectric conversion unit which is fixed on said first glass plate and generates power corresponding to input of light; and
a second glass plate which is disposed so as to cover said photoelectric conversion unit, wherein
at least a part of the periphery of said first glass plate and that of said second glass plate are melted and bonded to each other, and
a plurality of photoelectric conversion elements are connected in series or parallel in said photoelectric conversion unit.

2. The photoelectric conversion device according to claim 1, wherein
said photoelectric conversion unit includes a second bonding photoelectric conversion element or a thin-film photoelectric conversion element having at least a pair of PIN junctions.

3. The photoelectric conversion device according to claims 1, wherein
either said first glass plate or said second glass plate is a tempered glass plate.

4. The photoelectric conversion device according to claims 1, wherein
said second glass plate is thicker than said first glass plate.

5. The photoelectric conversion device according to claims 1, wherein
a low-refractive-index layer having a smaller index of refraction than said first glass plate is provided for a light receiving surface side of said first glass plate.

6. The photoelectric conversion device according to claims 1, wherein
an extraction part for extracting generated electric current is provided on said second glass plate, and
said extraction part includes through holes provided for said second glass plate, metal wires which penetrate said through holes and are connected to said photoelectric conversion unit, and a glass member which seals a gap between said through holes and said metal wires.

7. The photoelectric conversion device according to claim 1, further comprising:
a sealing member sandwiched between said first glass plate and said photoelectric conversion unit except for the periphery of said first glass plate,
wherein said first glass plate and said second glass plate are directly melted and bonded along the periphery of said first glass plate and said second glass plate.

8. The photoelectric conversion device according to claim 7, wherein
said first glass plate and said second glass plate are directly melted and bonded with at least one of said first glass plate and said second glass plate being bent.

9. The photoelectric conversion device according to claim 7, wherein
said first glass plate and said second glass plate are melted and bonded in a plurality of bonding regions including a first bonding region and a second bonding region outside the first bonding region, along the periphery of said first glass plate and said second glass plate.

10. The photoelectric conversion device according to claim 8, wherein
said first glass plate and said second glass plate are melted and bonded in a plurality of bonding regions including a first bonding region and a second bonding region outside the first bonding region, along the periphery of said first glass plate and said second glass plate.

11. The photoelectric conversion device according to claim 1, wherein
the photoelectric conversion device is directly formed on said first glass plate without the sealing member therebetween; and
said first glass plate and said second glass plate are melted and bonded in a plurality of bonding regions including a first bonding region and a second bonding region outside the first bonding region, along the periphery of said first glass plate and said second glass plate.

12. The photoelectric conversion device according to claim 11, wherein
said first glass plate and said second glass plate are directly melted and bonded along the periphery of said first glass plate and said second glass plate without the sealing member therebetween.

13. The photoelectric conversion device according to claim 11, wherein
said first glass plate and said second glass plate are directly melted and bonded with at least one of said first glass plate and said second glass plate being bent.

14. The photoelectric conversion device according to claim 12, wherein
said first glass plate and said second glass plate are directly melted and bonded with at least one of said first glass plate and said second glass plate being bent.
